(19) United States
(12) Patent Application Publication
(10) Pub. No.: US 2025/0311106 A1
(43) Pub. Date: Oct. 2, 2025

(54) FLOATING HARDWARE ON SUBSTRATE

(71) Applicant: FCI USA LLC, Etters, PA (US)

(72) Inventors: Dean Harmon, III, Etters, PA (US); Arkady Y. Zerebilov, Lancaster, PA (US)

(73) Assignee: FCI USA LLC, Etters, PA (US)

(21) Appl. No.: 19/090,209

(22) Filed: Mar. 25, 2025

Related U.S. Application Data
(60) Provisional application No. 63/570,202, filed on Mar. 26, 2024.

(51) Int. Cl. H05K 1/18; H05K 1/11; H05K 3/34

(52) U.S. Cl. CPC H05K 1/181; H05K 1/111; H05K 3/3431

(57) ABSTRACT

An assembly operable with a large number of high speed signals and including a plug connector pressure mounted to an electronic component that is also attached to a circuit board via an array of solder connections. A stack may be formed with the electronic component, a first component above, and a second component below the electronic component. All or a portion of the second component may fit between the electronic component and the circuit board. A force pressure mounting the plug to the electronic component may be generated by a fastener extending between the first component and the second component such that the force is transmitted along a force path that does not include the interface between the circuit board and electronic component. The assembly may include one or more structures to resist twisting the electronic component relative to the circuit board.

### CROSS-REFERENCE TO RELATED APPLICATIONS

This application claims the benefit under 35 U.S.C. § 119 (e) of U.S. Provisional Application Ser. No. 63/570,202, filed Mar. 26, 2024, and entitled “FLOATING HARDWARE ON SUBSTRATE,” the entire contents of which are incorporated herein by reference.

### BACKGROUND

Electrical connectors are used in many electronic systems. It is generally easier and more cost effective to manufacture a system as separate electronic subassemblies, such as printed circuit boards (PCBs), which may be joined together with electrical connectors. Having separable connectors enables components of the electronic system manufactured by different manufacturers to be readily assembled. Separable connectors also enable components to be readily replaced after the system is assembled, either to replace defective components or to upgrade the system with higher performance components.

Connectors may be arranged in configurations for interconnecting printed circuit boards. Sometimes, one or more smaller printed circuit boards may be connected to another larger printed circuit board. In such a configuration, the larger printed circuit board may be called a “motherboard” and the printed circuit boards connected to it may be called daughterboards. Also, boards of the same size or similar sizes may sometimes be aligned in parallel. Connectors used in these applications are often called “stacking connectors” or “mezzanine connectors.”

Cables have been used to make connections within the same electronic device. The cables may be used to route signals from an I/O connector to a processor assembly or other high performance chips that are located at the interior of a printed circuit board, away from the edge at which the I/O connector is mounted. In other configurations, both ends of a cable may be connected to the same printed circuit board. The cables can be used to carry signals between components mounted to the printed circuit board near where each end of the cable connects to the printed circuit board. In yet other system configurations, cables may be used to route signals between connectors that mate with daughterboards to the vicinity of a high performance chip, which may be near the interior of a printed circuit board, whether the same or a different printed circuit board to which the connector is mounted.

Known cables have one or more signal conductors, which is surrounded by a dielectric material, which in turn is surrounded by a conductive layer. A protective jacket, often made of plastic, may surround these components. Additionally, the jacket or other portions of the cable may include fibers or other structures for mechanical support.

High speed, high bandwidth cables and connectors have been used to route signals to or from processors and other electrical components that process a large number of high speed, high bandwidth signals. These cables and connectors reduce the attenuation of the signals passing to or from these components to a fraction relative to what might occur were the same signals routed over a similar distance through a printed circuit board. This benefit may be most pronounced at high frequencies, such as the frequencies required to support 112 Gbps or higher data rates.

To integrate such cables into an electronic system, they may be formed into cable assemblies. Within a cable assembly, one end of the cables may be terminated to a connector, such as an I/O connector. The other end of the cables may be terminated to a connector, sometimes called a near chip connector, that makes connections to a printed circuit board, either directly or through mating with another connector.

Fixed connections between electronic components are sometimes used. In a co-packaged architecture, an electronic component, such as a processor mounted to a substrate, may be soldered to a printed circuit board serving as a mother board for a server or other computing device. Ball Grid Array (BGA) mounting technology may be used for fixed connections between the electronic component and the printed circuit board. Connections to the electronic component may be made through cables using cable assemblies terminated with plugs that may be pressed against the electronic component.

Force to press the plugs against the electronic component may be generated by fasteners that, when tightened, pull the plugs toward the circuit board.

### SUMMARY

According to some aspects of the present technology, an electronic assembly includes: a circuit board comprising an opening; an electronic component; an array of solder connections coupling the electronic component to the circuit board; a first component on a first side of the electronic component, the first component comprising at least one attachment feature for attaching a plug to the electronic component; a second component disposed in the opening of the circuit board, the second component contacting the electronic component on a second side of the electronic component; and a fastener extending through the first component and the second component and urging the first component and the second component together.

According to some aspects of the present technology, an assembly comprises: a circuit board comprising an interface; an electronic component mounted to the circuit board at the interface; a first component coupled to a first side of the electronic component; a second component on a second side of the electronic component; and a plug pressed against the electronic component, wherein the plug is pressed against the electronic component with a force transmitted along a force path that extends through the first component and the second component but does not include the interface of the circuit board.

According to some aspects of the present technology, a method of manufacturing an electronic assembly, the electronic assembly comprising a circuit board comprising a first array of pads and an opening, includes: positioning a first component on a first side of an electronic component, the electronic component comprising a surface on a second side; positioning a second component on the second side of the electronic component; coupling the electronic component to the circuit board at an interface between the first array of pads and the surface on the second side of the electronic component; and tightening a fastener to generate a compressive force between the first component and a second component such that the first component is held against the electronic component.

Features described herein may be used, separately or together in any combination, in any of the embodiments discussed herein.

### BRIEF DESCRIPTION OF DRAWINGS

Various aspects and embodiments of the present technology disclosed herein are described below with reference to the accompanying figures. For the purposes of clarity, not every component may be labeled in every figure.

FIG. 1 is a perspective view of an exemplary assembly with a circuit board, an electronic component, and multiple pressure mount plugs, with low compressive force at an interface between the electronic component and the circuit board. Cables terminated with the plugs are shown cutaway for clarity.

FIG. 2 is a perspective view of the exemplary circuit board of the assembly of FIG. 1, revealing an opening and an array of pads for solder connections to the electronic component.

FIG. 3A is a perspective view of an exemplary stack of components, including an electronic component that may be mounted to the circuit board of FIG. 2 and a first component above the electronic component and a second component below the electronic component that may be pulled together for mechanical support and to provide a structure to which plugs may be attached.

FIG. 3B is a perspective view of an exemplary second component of the stack of FIG. 3A.

FIG. 3C is a bottom plan view of the stack of FIG. 3A, with bolts removed.

FIG. 3D is a partially exploded view of the stack of FIG. 3A, showing the second component and nuts that engage bolts to compress the stack exploded.

FIG. 4 is a partially exploded view of the stack of FIG. 3A, showing an exemplary electronic component, including a chip mounted on a substrate, and an exemplary first component, with the second component, bolts and nuts hidden.

FIG. 5A is a perspective view of the stack of FIG. 3A with the electronic component of the stack coupled to the circuit board and exemplary projections on the upper surface of the circuit board positioned to resist shear forces at an interface between the electronic component and the circuit board.

FIG. 5B is a sectional view of the coupled circuit board and electronic component of FIG. 5A.

FIG. 5C is a sectional view of a circuit board coupled to the stack including the electronic component, a first and second component as shown in FIGS. 3A-4 and additionally including a mechanical mount, as shown in FIG. 7B.

FIG. 6 is a perspective view of a portion of the circuit board and electronic component of FIGS. 5A-5B with a plurality of brackets positioned to reduce shear forces at the interface between the electronic component and circuit board.

FIG. 7A is a perspective view of an exemplary plug that may be pressure mounted to a surface of the electronic component, as shown in FIG. 1. Cables connected to the plug are shown cut away, but may extend from the plug for connection to other components (not shown) within an electronic system.

FIG. 7B is a perspective view of an exemplary mechanical mount configured to provide guidance when mounting the plug of FIG. 7A. The mechanical mount may be fastened in the stack along with or in place of the first component of FIG. 3A and may be separately attached to the stack and/or electronic component in alternative embodiments.

FIG. 7C is a perspective view of an electronic assembly with the mechanical mount of FIG. 7B coupled to the stack, including the electronic component, as in FIG. 1, but without plugs installed.

FIG. 8A is a sectional view of the exemplary assembly of FIG. 1, with through fasteners compressing the stack and a fastener passing through a projection of the plug and engaging the first component to hold the plug against the electronic component.

FIG. 8B is a schematic illustration of a force path that may result from mounting a plug with fasteners as illustrated in FIG. 8A.

FIGS. 9A-9C are schematic, plan views of a circuit board, such as may be used in a co-packaging assembly as illustrated in FIG. 1, illustrating alternative ways that openings for a second component may be formed either as through holes (FIGS. 9A and 9B) or as a channel that extends partially through the circuit board (FIG. 9C).

FIGS. 9D-9E are schematic sectional views through an assembly with the circuit board configuration shown in FIGS. 9A and 9B or as shown in 9C, respectively.

FIG. 10 is a flow chart of a method for manufacturing an electronic assembly, according to some embodiments.

### DETAILED DESCRIPTION

The inventors have recognized and appreciated designs for high reliability and high performance electronic assemblies with a large number of high speed signal paths. These techniques may enable routing of a large number of high speed signals between an electronic component and other portions of an electronic system. The electronic component, for example, may be connected to both a circuit board via soldered connections and to other locations through cables, which support the transmission of high speed signals. The cables may be terminated to plugs that mate to the electronic component. The electronic system may have a co-packaged architecture in which the electronic component may be a processor, such as one or more Graphical Processing Units (GPUs) mounted to a substrate, and the circuit board may be, for example, a mother board of a computing system.

Connections between the electronic component and the circuit board may be made through an array of solder connections, such as might result from using Ball Grid Array (BGA) mounting technology to attach the electronic component to the circuit board. The plugs may be connected to the electronic component at pressure mount interfaces. The inventors have recognized and appreciated that reliability of a high performance co-packaged system using these connection techniques together may be improved with plug mounting techniques that place little or no additional compressive force on the solder array interface.

Co-packaged systems may be used for computationally intensive operations, such as computing weights for a large language model. Such intensive computation consumes a large amount of power, which results in an elevated operating temperature, such as within the range of 85 to 105 Degrees-C. Mounting pressure mount plugs to the electronic component requires sufficient force to make reliable connections, and the amount of force increases in proportion to the number of connections that must be made. A high performance system may require 1,000 or more connections, which may require a force of 200 lbs or more or 250 lbs or more in some examples.

The contact force for pressure mount plugs may be generated by fasteners directly or indirectly engaged to the circuit board. The inventors have recognized and appreciated that such a mounting arrangement results in compressive force between the circuit board and the electronic component, which places the solder connections under compression. That compressive force may be comparable to the force required to hold one or more plugs against the electronic component.

The inventors have further recognized and appreciated that, particularly at the elevated operating temperatures of a high performance co-packaged electronic system, that amount of compressive force may degrade the mechanical and electrical integrity of the connections through the array of solder connections. The solder connections, for example, may crack or grow whiskers that short separate signal paths together or change the impedance of those paths. Techniques as described herein may provide for secure pressure mounting of one or more plug connectors to the electronic component without the need to place significant compressive force on the solder connections, thereby increasing the integrity of signals passing through the array of solder contacts.

Reliable pressure mounting of one or more plug connectors to the electronic component with little or no additional compressive force on the solder interface may be achieved in an assembly with a stack, including the electronic component and a first component, such as a top plate, above the electronic component and a second component, below the electronic component, These components may be held together as a result of compressive forces between the first and second component. The stack may exclude the circuit board. The second component may be shaped to expose an array of pads on the electronic component that may be connected through solder to corresponding pads on an upper surface of the circuit board.

Such a stack may be formed with one or more of the components in the assembly configured to enable the second component to fit between the electronic component and the circuit board. As a result, compressive force between the first component, which may be a top plate as in a conventional design, and the second component, which may function as a backer plate, is transmitted along a force path that does not include the interface between the circuit board and the electronic component. Nonetheless, fasteners that provide force for mounting pressure mount plugs may engage, directly or indirectly, the top plate, which is securely mounted relative to the electronic component as a result of fasteners between the first component above the electronic component and second component below the electronic component.

The inventors have further recognized and appreciated that such an arrangement may be created by forming one or more voids between the circuit board and the electronic component and positioning all or a portion of the second component in the voids. Such voids, for example, may be holes through the circuit board or may be one or more channels routed in a surface of the circuit board facing the electronic component. The channels may extend only partially through the circuit board. In other examples, instead of or in addition to removing material to create voids, voids might be created by adding material to increase the height of the circuit board in one or more locations, including the location of the interface to the electronic component.

Regardless of how the voids are formed, one or more fasteners may engage the second component, serving as a backer plate, within the voids. In this way, the force path provided by the fasteners does not pass through the circuit board and does not add any material compressive force to the solder array attaching the electronic component to the circuit board. The added compressive force at the interface may be, for example, less than 10 lbs or less than 5 lbs, in some examples.

Alternatively or additionally, the assembly may include one or more structures to resist twisting of the electronic component relative to the printed circuit board. Such features, for example, may reduce the chance of damage due to shear stress on the solder interface between the electronic component and the circuit board. The features may be surfaces on the printed circuit board transverse to the surface with pads to which the solder connections are made. These surfaces may be on projections extending from a surface of the circuit board facing the electronic components. The projections may be, for example, brackets attached to the surface of the circuit board. The brackets, for example, may be L-shaped, with one leg of the L-shaped bracket attached to the surface of the circuit board and a second, orthogonal leg of the bracket abutting a substrate of the electronic component or other component in the stack.

Alternatively or additionally, in examples in which the interface between the electronic component and the circuit board is in a plane that is below the uppermost surface of the circuit board, surfaces of the circuit board bounding one or more of the voids may be positioned to inhibit twisting motion of the electronic component relative to the circuit board.

In one aspect, assemblies as described herein may enable force pressing a plug against a substrate of an electronic component with low force and/or stress on solder connections to that substrate. In one aspect, assemblies as described herein may support a pressure mount interface to a substrate operating in high temperatures, such as at least 85 degrees-C. In one aspect, assemblies as described herein may mitigate shear stress on the solder connections, by restricting the electronic component from rotating relative to the circuit board during operation of the assembly.

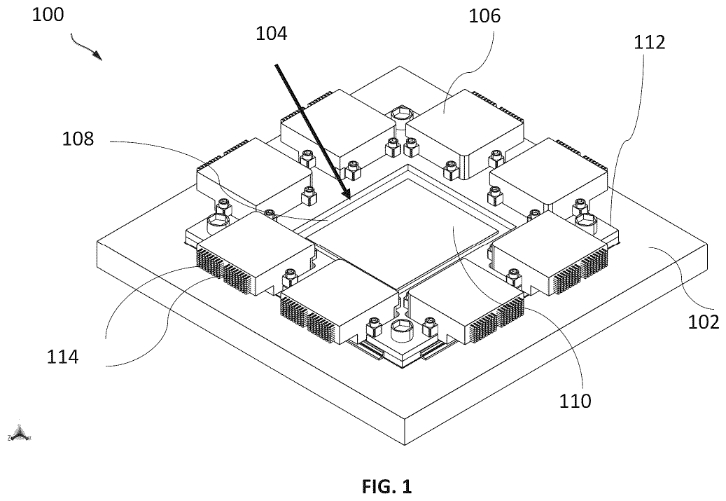

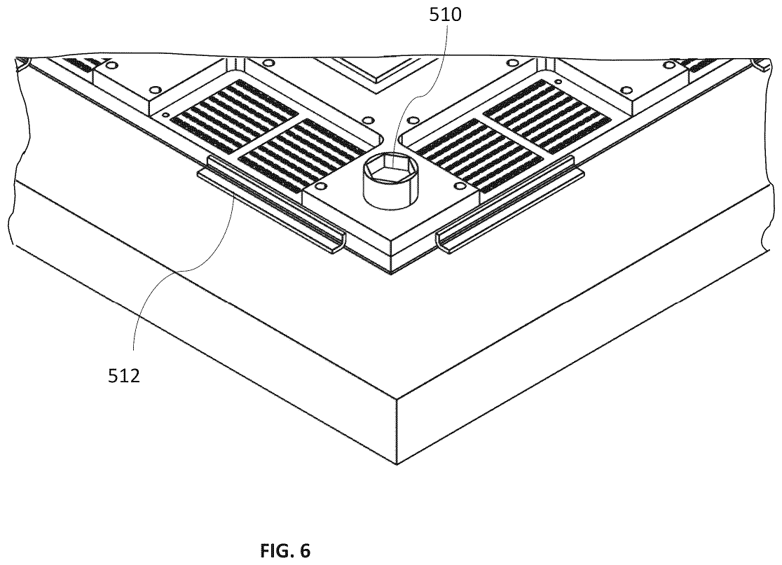

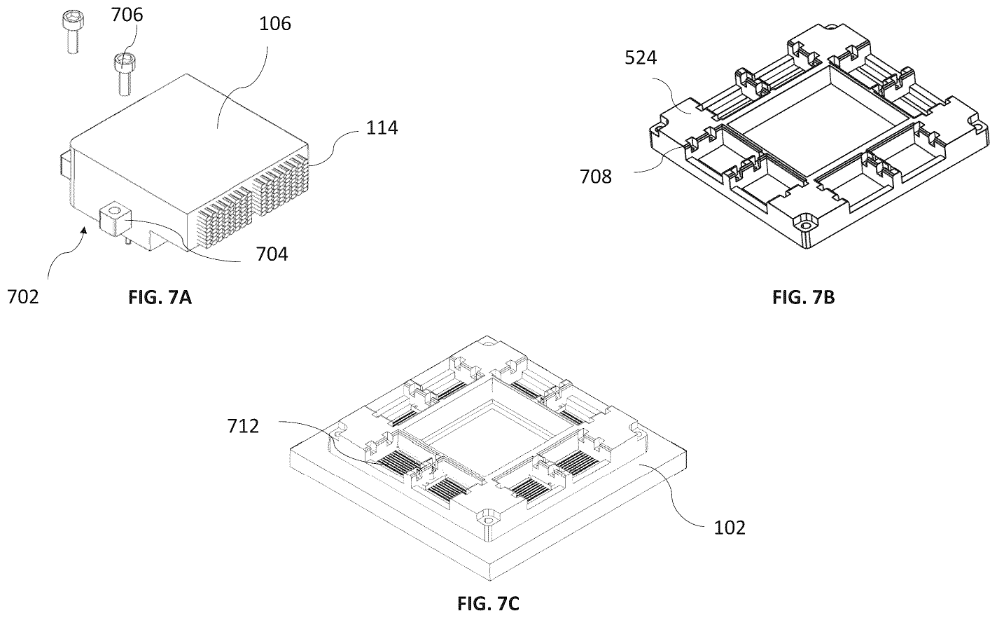

FIG. 1 illustrates an example assembly 100 with a circuit board 102, an electronic component 104, and plugs 106 pressure mounted to an upper surface of the electronic component. The assembly may be assembled according to techniques described herein, and the assembly may include more components or fewer components than those shown in FIG. 1, as the techniques are not so limited. As one example, a mechanical mount as discussed in connection with FIG. 7B may be included in the assembly, in some examples.

The circuit board may be configured as a motherboard. The circuit board may be a structure with conductors to pass signals. An example of this structure includes but is not limited to a printed circuit board (PCB). An electronic component may be coupled to the circuit board. An array of solder connections may couple the electronic component to the circuit board. As an example, a ball grid array (BGA) may be used. The BGA may include thousands of solder balls. In some embodiments, the electronic component is mounted to the circuit board such that pads of the circuit board align with pads of the electronic component, such that solder balls on one of the sets of pads, when reflowed, couple the sets of pads.

The electronic component 104 may include a substrate 108 and one or more chips 110. A chip may be a processor chip, such as a GPU or an array of GPUs. The chip may be disposed on a side of the electronic component.

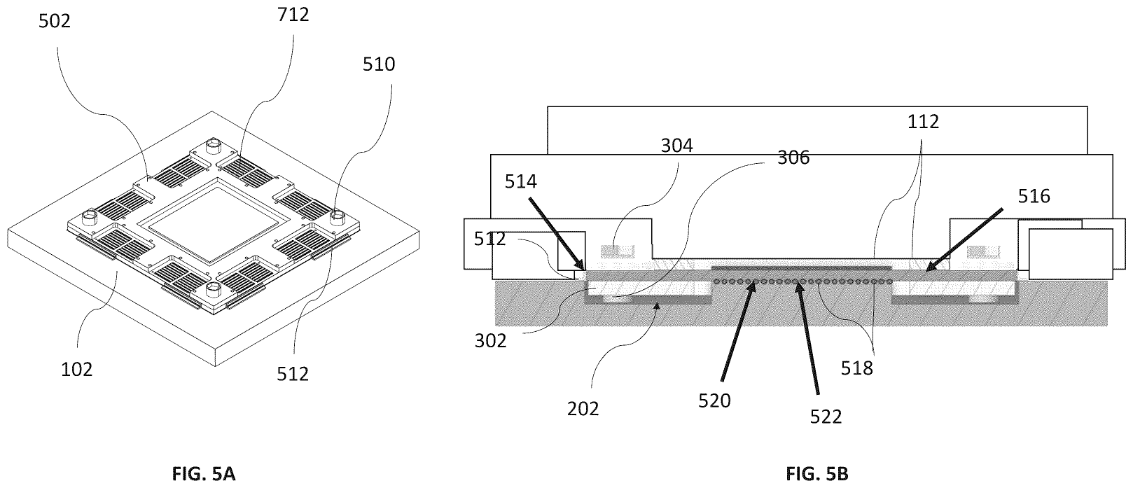

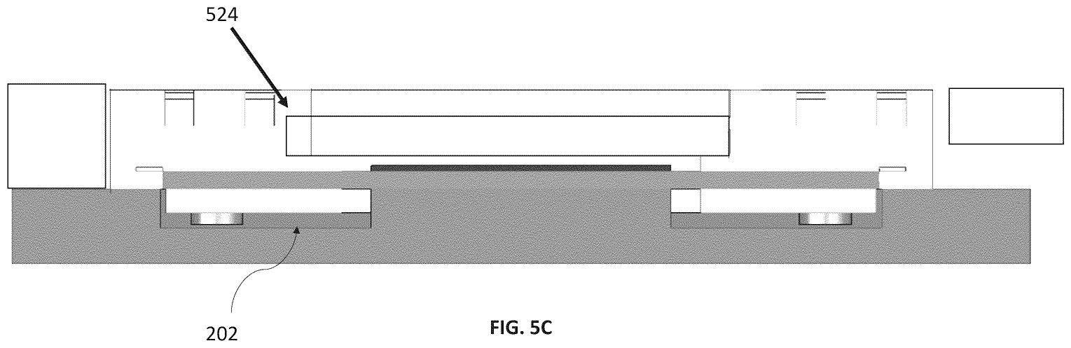

In the example shown in FIG. 1, a first component 112 may be coupled to the electronic component. The first component may be a stiffener. As an example, a stiffener ring may be included so that during reflow processing, warpage of the substrate of the electronic component is reduced. In some embodiments, the first component is a top plate. The first component may be held to the electronic component at an upper surface of the electronic component. The first component may be held using an adhesive 516 or using bolts that engage a second component below the substrate (e.g., as shown in FIG. 5B). The first component may be made of metal, ceramic, or another suitable material.

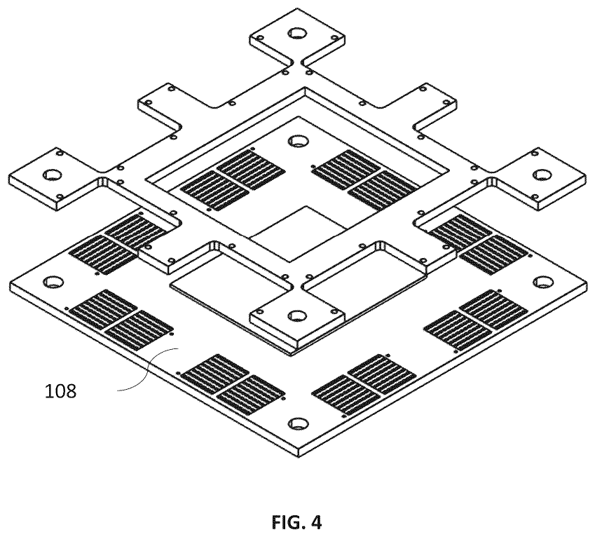

An exemplary first component may include at least one attachment feature for attaching a plug to the electronic component. The plug connector may terminate cables 114, which are shown cut away in FIG. 1. The attachment feature may be means to attach the plug, including a threaded hole that receives a screw, as shown in FIG. 4 as an example. Alternatively or additionally, a latch or another suitable structure may be included as an attachment feature to hold down the plug. The hold down force may be between 100 and 200 Newtons per plug, such as approximately 140 Newtons per plug.

In some examples, the first component may be configured to aid in attaching the plugs. The first component, for example, may include openings in which the plugs are inserted and may in some examples include attachment features for attaching plugs. The fasteners may include bolts, for example.

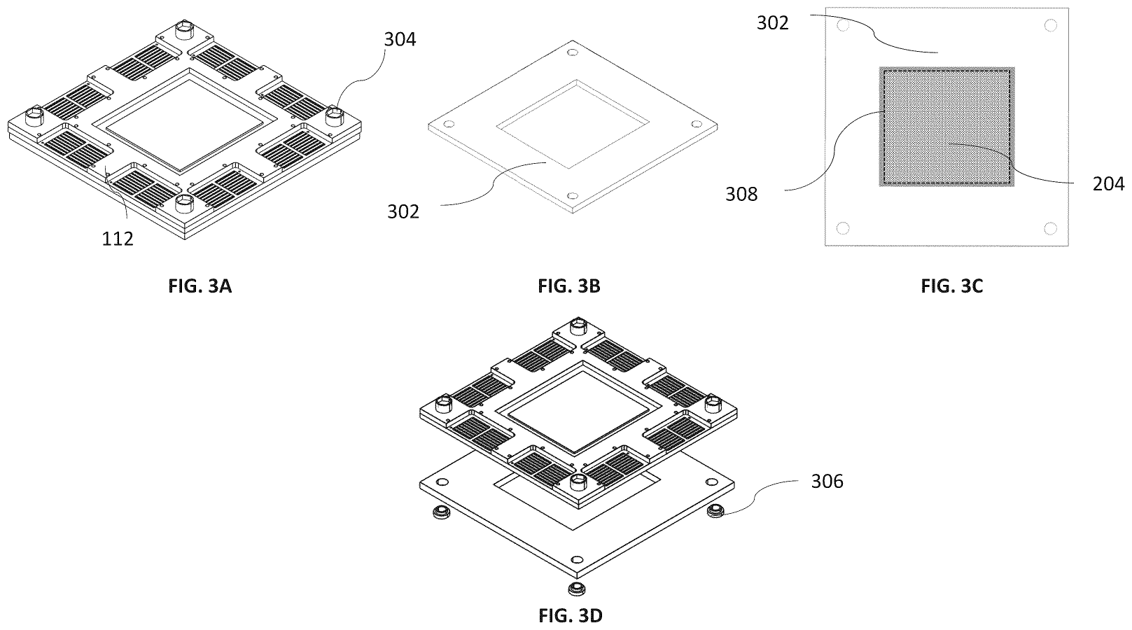

According to some embodiments, the example electronic component may be coupled to a second component 302 (e.g., as shown in FIG. 3C). The second component may be held to the substrate. As with the first component, the second component may contain one or more sub-parts and may be held to the electronic component via an adhesive and/or via compressive force generated by tightening a fastener that pulls the second component towards the electronic component. The second component may have a first surface facing the electronic component and a second surface opposite the first surface. The second component may contact the electronic component and/or may be on a side of the electronic component opposite the side that the first component is on (e.g., a first side and a second side).

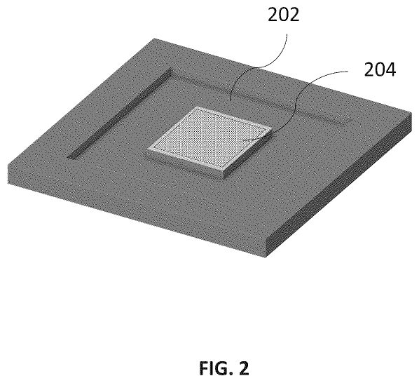

The circuit board may be configured for coupling to an electronic component. FIG. 2 illustrates the example circuit board of FIG. 1. As shown in FIG. 2, the circuit board may include an opening 202. The circuit board may also include a plurality of pads 204. The pads may be disposed in the region shown in FIG. 2 (schematically shown). The pads may be arranged in a suitable configuration, such as a regular array. Solder balls on the lower surface of the electronic component may fuse to these pads during a reflow operation to make connections between the electronic component and the circuit board.

In the example of FIG. 2, the circuit board has an opening, which here extends only partially through the circuit board. Such an opening may be formed in a drilling or routing operation, for example. The opening may receive a portion of a stack of components including the electronic component to be connected to the printed circuit board.

FIG. 3A illustrates an example stack of components. The stack may include the first component and may include the electronic component. The first component may surround partially or fully the chip (e.g., as shown in FIG. 3A). In this example, the stack is held together with bolts 304 that may be tightened to pull together the first component above the upper surface of the electronic component and the second component below the lower surface of the electronic component.

FIG. 3B illustrates an example second component that may be included in the stack of FIG. 3A. The second component may be a stiffener or a backer plate. In some examples, the second component is a bottom plate. The second component may be in contact with a bottom surface 308 of the substrate of an electronic component, as shown in FIG. 3C.

FIG. 3C is a bottom view of an exemplary stack, with a portion of the electronic component exposed through an opening in the second component. As shown in FIG. 3C, the electronic component may include a bottom surface. The bottom surface may include a plurality of pads (schematically shown). These pads may align with the pads on the circuit board, as shown in FIG. 2. Solder balls may be fused to the pads on either of these arrays of pads such that when the stack including the electronic component is placed on the circuit board it may be heated to reflow the solder of the solder balls to make solder connections between the electronic component and the circuit board.

FIG. 3D shows a partially exploded view of the example stack of FIG. 3A. As shown in FIG. 3D, the second component may be disposed below the substrate and the first component. FIG. 3D shows nuts 306 that may engage bolts to compress the example stack shown in an exploded view. Separate nuts are not shown in FIG. 3C, but may be present. Alternatively or additionally, the holes in the second component may be threaded to engage the bolts inserted through the first component and the electronic component from the top side of the stack such that the nut for the bolt is integrated with the second component.

FIG. 4 shows a partially exploded view of the substrate and first component of FIG. 3A. In some embodiments, the first component has one integrated piece. Optionally, the first component may have two or more pieces.

According to some embodiments, the circuit board and electronic component may be coupled. FIG. 5A is a perspective view of the example stack of FIG. 3A, with the electronic component of the stack soldered to the circuit board. As with the example of FIG. 3A, an optional mechanical mount as in FIG. 7B is not included.

FIG. 5B is a sectional view of the coupled circuit board and electronic component. The example shown in FIG. 5B may include the mechanical mount but is not included in the shown example. For completeness, FIG. 5C shows a sectional view of a coupled circuit board and electronic component with a mechanical mount 524 as in FIG. 7B, attached to the first component. While FIG. 5C shows an example of a first component and a mechanical mount, in other examples, the mechanical mount may be used in place of the first component.

The electronic component and circuit board may be coupled using solder connections 518, (not shown in FIG. 5C). As shown in FIG. 5B, at an interface 520 of the circuit board, an electronic component may be mounted. Solder balls, such as a BGA, may be disposed on the bottom surface of the electronic component and disposed at the interface when the electronic component is mounted. The pads of the circuit board may align with pads of the electronic component with the solder ball material in between (e.g., there may be one or more surfaces 522 with pads). The electronic component and the circuit board may undergo a reflow process which may melt the solder material and couple the pads such that electrical connection can be made.

FIG. 5B is a sectional view showing at least portions of the second component disposed within the opening of the circuit board. Similarly, the nut that cooperates with a fastener 510 extending through the stack to provide compressive force on the stack alternatively or additionally may be disposed within the opening of the circuit board. The nut may be part of the fastener that extends through the first component and the second component, in some embodiments.

Referring back to FIG. 5A, in some embodiments, a fastener may extend through the first component and the second component. Optionally, the fasteners may extend through the electronic component. The fastener may urge the first component and the second component together. Urging the first component and the second component together may clamp the first and second components around the electronic component, holding the electronic component and the first and second components in a stack with sufficient mechanical integrity for the first component to serve as an anchor point for fasteners that may pull the plugs toward the upper surface of the electronic component. The fastener may engage a second surface of the second component that is opposite a first surface facing the electronic component. The fastener may engage the second surface within an opening of the circuit board. The second component may be disposed in the opening of the circuit board. The fastener may include the nut described in relation to FIG. 3D or FIG. 5B. As shown in the sectional view of FIG. 5B, the fastener may include a bolt. The bolt may extend through the first component and the second component. The nut may be within the opening of the circuit board and may be threaded on the bolt. FIG. 6 shows a portion of the circuit board and the stack including the electronic component of FIGS. 5A-5B with a plurality of brackets 512 and a fastener.

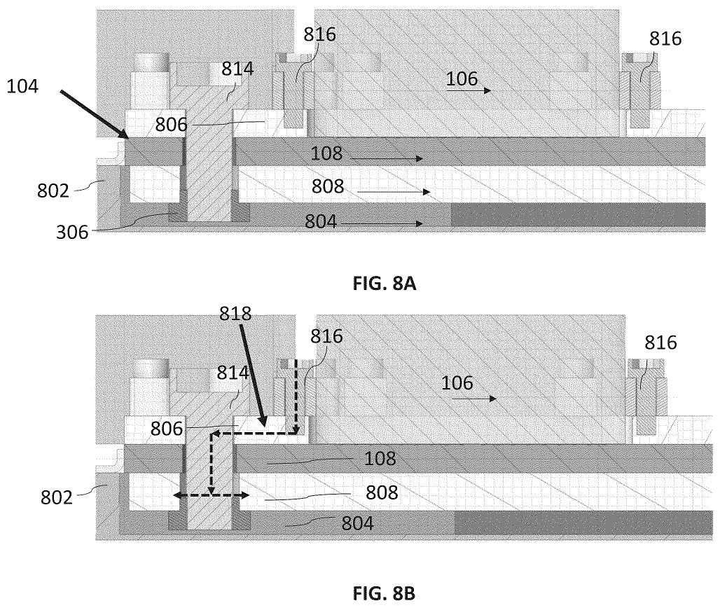

Without wishing to be bound by any particular theory, including the second component can enable a force path to extend through the first component and the second component but not the portion of the circuit board to which the electronic component is mounted (e.g., as described in relation to FIG. 8B). The stack, including components that generate compressive force to attach one or more plugs to the electronic component, may be regarded as floating relative to the circuit board. By mitigating the force imparted on the interface, the force may be reduced on the solder ball joints. In some embodiments, by screwing the first component and second component together, the first and second component may not separate in the vertical direction under certain operating conditions such as heats above 85 degrees-C. In some embodiments, the bolts may keep components of the assembly from peeling apart.

Optionally, one or more other features may be included in the assembly to reduce stress on the solder interface between the electronic component and the circuit board. Shear stress hardware may be coupled to the circuit board and substrate, for example, to resist rotation of the electronic component relative to the circuit board. The shear stress hardware may include one or more surfaces of the circuit board that abut the substrate or other component of the stack.

In some examples, the surface may be on a projection from the surface of the circuit board facing the electronic component. The shear stress hardware may include a plurality of brackets, for example.

The example brackets may serve as ribs contacting the electronic component or other component of the stack including the electronic component. The brackets may block rotation by holding the substrate in the X, Y directions. In some embodiments, such as shown in FIG. 5B, a plurality of transverse surfaces 514 that block rotation may extend transverse to the surface of the circuit board with pads. In some embodiments, the transverse surface is on a projection such as shown in FIG. 5B. The example electronic component may include a substrate with a surface having pads and an edge perpendicular to that surface. In some embodiments, the brackets have a first side adhered to the surface of the circuit board that has pads (e.g., pads coupled to pads of the substrate) and the brackets have a second side that abuts the edge of the substrate that is perpendicular to the surface of the substrate that has pads. The brackets may be adhered using an adhesive and/or by soldering, for example. According to some embodiments, the shear stress hardware may include projections extending above the surface of the circuit board that has pads, and the projections may include the transverse surfaces of the circuit board. The brackets may be configured to restrict rotation of the substrate relative to the circuit board.

The example circuit board may have a plurality of transverse surfaces to block rotation of the electronic component and otherwise reduce shear stress on the solder interface. The transverse surfaces may extend transverse to the surface of the circuit board with a plurality of pads. The transverse surfaces may abut the edge of the substrate perpendicular to the surface of the substrate that has pads. In assemblies in which some portion of the stack extends below the upper surface of the circuit board into the opening(s) of the circuit board, the transverse surfaces may bound the openings of the circuit board. As an example, the substrate may be recessed into the circuit board. The transverse surface may abut an edge of the substrate that is perpendicular to the surface of the substrate with pads (not shown). The transverse surfaces may be positioned to restrict rotation of the substrate with respect to the circuit board.

In the example shown in FIG. 5A, the stack includes a first component that has a plurality of attachment features 502. The attachment features may be used to attach one or more plugs, and may be, for example, one or more threaded holes that each receive a bolt. The attachment features may be sized to receive a bolt for attaching a plug. The substrate of the electronic component may include contacts. The contacts may facilitate electrical connection with the plug. In some embodiments, the contacts may be pads 712 and they may be aligned such that, when the plugs are secured via the attachment features, contacts in the plug make contact with the pads.

Attachment features that support the fasteners that extend through the first component and the second component may be different than the attachment features for the plugs. The attachment features that hold the stack together may be sized to receive fasteners extending through the first component and the second component. The attachment features may vary in size and the fasteners that secure the plugs may be smaller than the fasteners that hold the stack together.

One or more plugs may be coupled to the first component. FIG. 7A shows an example plug. Cables may be connected to the plug (here shown cutaway for simplicity of illustration). Each plug may include one or more attachment features. The attachment feature may be configured to provide means for fastening the plug to press it against a surface of the substrate of the electronic component to form a reliable pressure mount interface 702. In some embodiments, the attachment features 704 for the plugs may include a hole configured to receive a fastener 706. The hole may be through a flange, for example. A fastener, such as a bolt shown in FIG. 7A, may be tightened when inserted in the hole to press the plug against the electronic component. The fastener may couple to the first component, such as shown in FIG. 8A such that the plug is mounted at a pressure mount interface.

FIG. 7B illustrates a mechanical mount which might be used instead of or in addition to the first component of the stack as pictured above. In some examples, the mechanical mount may be a sub-part of the first component on the upper side of the electronic component. In such an example, bolts passing through the first component to engage a second component on the opposite side of the electronic component may pass through the mechanical mount and hold it in the stack with the electronic component. In other examples, the mechanical mount may be attached to the assembly separate from the stack.

The mechanical mount may provide guidance for mounting the plug(s). If separate from the first component, the mechanical mount may be attached to the electronic component using an adhesive. Alternatively or additionally, a mechanical mount may be attached to the first component or other component of the stack using fasteners.

In the example of FIG. 7B, the mechanical mount includes attachment features 708 that are configured to provide means for fastening the plugs and include openings for inserting fasteners to hold the stack together. In some embodiments, the attachment feature may include a hole configured to receive a bolt. Alternatively or additionally, a mechanical mount may be part of the first component; the mechanical mount may be attached to the first component with the same fasteners that compress the electronic component between the first and second components; the mechanical mount may be attached to the first component with fasteners different than the ones that compress the electronic component between the first and second components; or the mechanical mount may not be attached to the first component and may be held to the electronic component in another suitable way, such as using adhesive or fasteners attached to the electronic component.

FIG. 7C illustrates the mechanical mount of FIG. 7B coupled to the electronic component of a stack of FIG. 1. The substrate of the example electronic component may include pads 712 for mating to a plug pressed against the surface. The plug shown in FIG. 7A may be mounted to the mechanical mount shown in FIG. 7C. Referring back to FIG. 1, a plurality of plugs is shown pressure mounted to the electronic component.

Each plug may be attached using the attachment features of the first component and/or a mechanical mount, if present. Alternatively or additionally, the plug may be attached to the substrate with or without some or all of the attachment features. In some embodiments, the plug may be pulled down by an attachment feature and may be attached directly to the substrate. In some embodiments, the plug may be connected through a hole in the substrate and a hole in the first component to the second component. In some embodiments, the fasteners may go to and/or through the mechanical mount, if present.

As described herein, the assembly may include plugs and a circuit board. FIG. 8A illustrates a sectional view of the example assembly of FIG. 1 including the plugs 106 and circuit board. As shown in FIG. 8A, the circuit board may be a mother board 802 and may include a cored cavity 804, such as an opening in the circuit board. The assembly may include a first component such as a top plate 806. The assembly may include a second component such as a backer plate 808. The assembly may include a substrate 108. A fastener including a nut 306 and screw 814 may be included. As shown, the screw extends through the top plate and the backer plate. An integrated screw 816 may be included to hold down the plug.

FIG. 8B is a schematic illustration of a force path 818 that may result from mounting a plug as shown in FIG. 8A. As shown in FIG. 8B, in some embodiments, in which a plug is pressed against an electronic component, a force may be transmitted along a force path that extends through a first component (e.g., the top plate) and a second component (e.g., the backer plate) but does not include an interface of the circuit board (not shown in the illustrated view), an example of the interface is shown in FIG. 5B. The force of mounting the plugs may be greater than 250 pounds.

Without wishing to be bound by any particular theory, the force path extending through the first component and the second component but not the portion of the circuit board to which the electronic component is mounted may remove or reduce the force imparted on the interface such that the force may be removed from or reduced on solder ball joints that may be used.

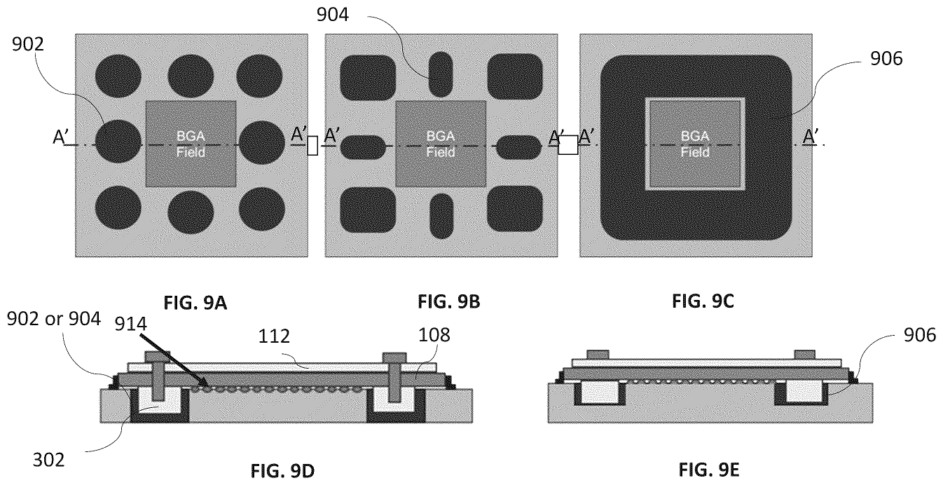

In some embodiments, the circuit board may include voids, or openings. The void may include a hole or may include a channel, for example. As shown in FIG. 9A, the circuit board may include circular holes 902. The circuit board may include one or more holes, such as five holes, eight holes, or ten holes. The holes may be through holes extending through the circuit board. The circuit board may include an array of pads that forms the BGA field 914 for attaching solder balls on the electronic component to the circuit board. As shown in FIG. 9B, the holes 904 may have an oval shape. The holes may have a rectangular shape. The holes shown in FIG. 9B may be through holes. In examples in which multiple discrete openings are in the circuit board, the second component may be one or more members that collectively extend into some or all of the holes and are engaged by fasteners extending through the first component of the stack.

As shown in FIG. 9C, the circuit board may include a channel 906. The channel may surround an array of pads for solder connections.

In some embodiments, the example second component may be in the voids partially. In some embodiments, the second component may be entirely within a void, such as a channel. In some embodiments, at least one spacer may extend through the opening(s). The spacers may be separate components from the second component, in some embodiments. The spacers may be integrated with the second component or the substrate, in some embodiments.

FIG. 9D illustrates a sectional view of the circuit board configuration shown in FIG. 9A and FIG. 9B taken along the line A′-A′. As shown in FIG. 9D, the circuit board of FIGS. 9A and 9B may be coupled to a substrate (not shown in FIGS. 9A and 9B) using the BGA. The substrate may be coupled to a first and second component. FIG. 9E illustrates a sectional view of the circuit board configuration shown in FIG. 9C taken along the line A′-A′.

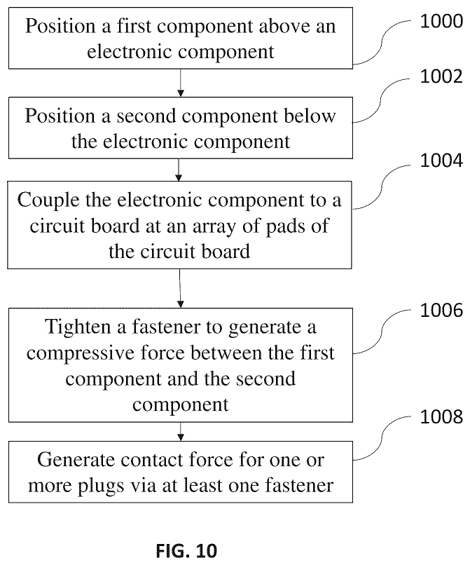

FIG. 10 is a flow chart of a method for manufacturing an electronic assembly. The electronic assembly may be an electronic assembly as described herein. The electronic assembly may include a circuit board with an array of pads and an opening.

As shown in FIG. 10, step 1000 may include positioning a first component above an electronic component. As an example, the electronic component may be or include a substrate with one or more chips mounted to it. The first component may be the first component shown in FIG. 3A. Step 1000 may include positioning the first component on a first side of the electronic component which has a surface on a second side.

Step 1002 may include positioning a second component below the electronic component. In some embodiments, the second component may be the second component shown in FIG. 3B. Step 1002 may include positioning the second component on the second side of the electronic component.

Step 1004 may include coupling the electronic component to a circuit board at an array of pads of the circuit board. The circuit board may be the circuit board shown in FIG. 5A. The electronic component may be coupled to the circuit board at an interface between an array of pads and the surface on the second side of the electronic component. The second component may include at least a portion positioned within an opening of the circuit board such that the position of the second component is disposed between the electronic component and the circuit board.

Step 1006 may be performed before step 1004 in some embodiments or may be performed after step 1004 in some embodiments. Step 1006 may include tightening a fastener to generate a compressive force between the first component and the second component. The fastener may be the fastener, such as a bolt, shown in FIG. 5A. The first component may be held against the electronic component as a result of the tightening.

Step 1008 may include generating contact force for one or more plugs via at least one fastener. The one or more plugs may be the plurality of plugs shown in FIG. 1, in some embodiments. The plug may include in excess of 1,000 contacts. The at least one fastener may be the fastener shown in FIG. 7A. The fastener may engage the first component. Step 1008 may include tightening a fastener to press a pressure mount plug connector against the electronic component with a force in excess of 200 lbs or 250 lbs in some examples. Tightening the fastener may increase the compressive force on the attachment between the first component and electronic component by less than 10 lbs, or less than 5 lbs, in some examples.

Steps 1000-1008 may be performed in the order shown in FIG. 10 or may be performed in another suitable order. One or more steps shown may be performed, and one or more additional steps not shown may be performed. As an example, the steps may further include operating the electronic component in an environment of at least 85 degrees-C.

The disclosed technology is not limited in its application to the details of construction and the arrangement of components set forth in the preceding description or as illustrated in the drawings. The disclosed technology is capable of other embodiments and of being practiced or of being carried out in various was. Also, the phraseology and terminology used herein is for the purpose of description and should not be regarded as limiting. The use of “including,” “comprising,” “having,” “containing,” or “involving,” and variations thereof herein, is meant to encompass the items listed thereafter and equivalents thereof as well as additional items.

Having thus described several aspects of at least one embodiment of this invention, it is to be appreciated that various alterations, modifications, and improvements will readily occur to those skilled in the art.

For example, a stack is illustrated held together by compressive force generated by a bolt inserted from the top of the stack. In other examples, the bolt may be inserted from the bottom of the stack.

As another example, FIG. 9D illustrates the second component(s) fully contained within holes in the circuit board. In embodiments in which the holes extend through the circuit board, the second component may extend outside out of the hole but, if aligned with the hole, even when pulled toward the first component of the stack does not compress the interface between the circuit board and the electronic component.

Further, additional components may be present without interfering with operations as described herein. For example, spacers may be around a fastener drawing the first component and the second component of the stack together. Alternatively or additionally, springs or other compliant members may be positioned between a stack and a circuit board to support the stack, but without transmitting significant force into the circuit board that might apply compressive force or rotational stress on the interface between the circuit board and the electronic component.

As another example, some fasteners were pictures as threaded elongated members that engage other members, which may be described as being or including either a bolt or a screw. The fasteners alternatively may be latches, clasps, or have other structures.

Such alterations, modifications, and improvements are intended to be part of this disclosure and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Also, circuits and modules depicted and described may be reordered in any order, and signals may be provided to enable reordering accordingly.

### Examples

In a first example, an electronic assembly may include a circuit board comprising an opening; an electronic component; an array of solder connections coupling the electronic component to the circuit board; a first component on a first side of the electronic component, the first component comprising at least one attachment feature for attaching a plug to the electronic component; a second component disposed in the opening of the circuit board, the second component contacting the electronic component on a second side of the electronic component; and a fastener extending through the first component and the second component and urging the first component and the second component together.

In a second example, an assembly may include a circuit board comprising an interface; an electronic component mounted to the circuit board at the interface; a first component coupled to a first side of the electronic component; a second component on a second side of the electronic component; and a plug pressed against the electronic component, wherein the plug is pressed against the electronic component with a force transmitted along a force path that extends through the first component and the second component but does not include the interface of the circuit board.

Optionally, the second component may include a first surface facing the electronic component and a second surface opposite the first surface; and the fastener may engage the second surface of the second component.

Optionally, the fastener may engage the second surface of the second component within the opening of the circuit board.

Optionally, the fastener may include: a bolt extending through the first component and the second component; and a nut within the opening of the circuit board threaded on the bolt.

Optionally, the nut may include a threaded opening in the second component.

Optionally, the first component may be adhered to the electronic component.

Optionally, the electronic assembly may further include a plurality of ribs contacting the electronic component.

Optionally, the circuit board may have a first surface comprising a first plurality of pads; the electronic component may comprise a substrate having a second surface comprising a second plurality of pads and an edge perpendicular to the second surface; and the solder connections may couple the first plurality of pads to the second plurality of pads.

Optionally, the circuit board may comprise a plurality of transverse surfaces extending transverse to the first surface; and the transverse surfaces may abut the edge of the substrate.

Optionally, the transverse surfaces may be positioned to restrict rotation of the substrate with respect to the circuit board.

Optionally, the circuit board may comprise a plurality of brackets, each of the plurality of brackets having a first side adhered to the first surface of the circuit board and a second side abutting the edge of the substrate.

Optionally, the assembly may further comprise a plurality of projections extending above the first surface of the circuit board, and the projections may comprise the transverse surfaces.

Optionally, the circuit board may have a first surface comprising a first plurality of pads; the electronic component may comprise a substrate having a second surface comprising a second plurality of pads and an edge perpendicular to the second surface; the solder connections may couple the first plurality of pads to the second plurality of pads; and the assembly may further comprise a plurality of brackets configured to restrict rotation of the substrate relative to the circuit board.

Optionally, the opening may be a hole through the circuit board.

Optionally, the opening may be a channel in the circuit board surrounding the array of solder connections.

Optionally, a chip may be disposed on the first side of the electronic component.

Optionally, the first component may comprise a stiffener.

Optionally, the first component may comprise a top plate.

In a third example, a method of manufacturing an electronic assembly comprising a circuit board comprising a first array of pads and an opening may include: positioning a first component on a first side of an electronic component, the electronic component comprising a surface on a second side; positioning a second component on the second side of the electronic component; coupling the electronic component to the circuit board at an interface between the first array of pads and the surface on the second side of the electronic component; and tightening a fastener to generate a compressive force between the first component and a second component such that the first component is held against the electronic component.

Optionally, the method may additionally comprise: tightening a second fastener to press a pressure mount plug connector against the electronic component with a force in excess of 200 lbs.

Optionally, tightening the second fastener may increase the compressive force on the attachment between the first component and the electronic component by less than 5 lbs.

Optionally, the pressure mount plug connector may comprise in excess of 1,000 contacts.

Optionally, the method may additionally comprise operating the electronic component in an environment of at least 85 degrees-C.

Optionally, the second fastener may engage the first component.

Optionally, the second component may comprise at least a portion positioned within the opening of the circuit board such that the portion of the second component is disposed between the electronic component and the circuit board.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The invention claimed is:

1. An electronic assembly, comprising:
a circuit board comprising an opening;
an electronic component;
an array of solder connections coupling the electronic component to the circuit board;
a first component on a first side of the electronic component, the first component comprising at least one attachment feature for attaching a plug to the electronic component;
a second component disposed in the opening of the circuit board, the second component contacting the electronic component on a second side of the electronic component; and
a fastener extending through the first component and the second component and urging the first component and the second component together.

2. (canceled)

3. The electronic assembly of claim 1, wherein:
the second component comprises a first surface facing the electronic component and a second surface opposite the first surface; and
the fastener engages the second surface of the second component; and/or
the fastener engages the second surface of the second component within the opening of the circuit board.

4. (canceled)

5. The electronic assembly of claim 1, wherein the fastener comprises:
a bolt extending through the first component and the second component; and
a nut within the opening of the circuit board threaded on the bolt, wherein the nut comprises a threaded opening in the second component.

6.-8. (canceled)

9. The electronic assembly of claim 1, wherein:
the circuit board has a first surface comprising a first plurality of pads;
the electronic component comprises a substrate having a second surface comprising a second plurality of pads and an edge perpendicular to the second surface; and
the solder connections couple the first plurality of pads to the second plurality of pads.

10. The electronic assembly of claim 9, wherein:
the circuit board comprises a plurality of transverse surfaces extending transverse to the first surface;
the transverse surfaces abut the edge of the substrate; and
the transverse surfaces are positioned to restrict rotation of the substrate with respect to the circuit board.

11. (canceled)

12. The electronic assembly of claim 10, wherein:
the circuit board comprises a plurality of brackets, each of the plurality of brackets having a first side adhered to the first surface of the circuit board and a second side abutting the edge of the substrate.

13. The electronic assembly of claim 10, wherein:
the assembly further comprises a plurality of projections extending above the first surface of the circuit board, and the projections comprise the transverse surfaces.

14. The electronic assembly of claim 1, wherein:
the circuit board has a first surface comprising a first plurality of pads;
the electronic component comprises a substrate having a second surface comprising a second plurality of pads and an edge perpendicular to the second surface;
the solder connections couple the first plurality of pads to the second plurality of pads;
the assembly further comprises a plurality of brackets configured to restrict rotation of the substrate relative to the circuit board.

15. The electronic assembly of claim 1, wherein:
the opening is a hole through the circuit board.

16. The electronic assembly of claim 1, wherein:
the opening is a channel in the circuit board surrounding the array of solder connections.

17. The electronic assembly of claim 1, wherein a chip is disposed on the first side of the electronic component.

18.-19. (canceled)

20. A method of manufacturing an electronic assembly comprising a circuit board comprising a first array of pads and an opening, the method comprising:
positioning a first component on a first side of an electronic component, the electronic component comprising a surface on a second side;
positioning a second component on the second side of the electronic component;
coupling the electronic component to the circuit board at an interface between the first array of pads and the surface on the second side of the electronic component; and
tightening a fastener to generate a compressive force between the first component and a second component such that the first component is held against the electronic component.

21. The method of claim 20, additionally comprising:
tightening a second fastener to press a pressure mount plug connector against the electronic component with a force in excess of 200 lbs, wherein:
tightening the second fastener increases the compressive force on attachment between the first component and the electronic component by less than 5 lbs.

22. (canceled)

23. The method of claim 21, wherein the pressure mount plug connector comprises in excess of 1,000 contacts and/or wherein the second fastener engages the first component.

24. The method of claim 21, additionally comprising:
operating the electronic component in an environment of at least 85 degrees-C.

25. (canceled)

26. The method of claim 20, wherein
the second component comprises at least a portion positioned within the opening of the circuit board such that the portion of the second component is disposed between the electronic component and the circuit board.

27. An assembly, comprising:
a circuit board comprising an interface;
an electronic component mounted to the circuit board at the interface;
a first component coupled to a first side of the electronic component;
a second component on a second side of the electronic component; and
a plug pressed against the electronic component,
wherein the plug is pressed against the electronic component with a force transmitted along a force path that extends through the first component and the second component but does not include the interface of the circuit board.

28. The assembly of claim 2, wherein the first component is adhered to the electronic component.

29. The assembly of claim 2, further comprising a plurality of ribs contacting the electronic component.

30. The assembly of claim 2, wherein the first component comprises a stiffener or a top plate.
